(19) United States
(12) Patent Application Publication
(10) Pub. No.: US 2014/0312933 A1
(43) Pub. Date: Oct. 23, 2014

(54) LOW NOISE COMPARATOR FOR HIGH RESOLUTION ADC

(71) Applicant: KOREA ELECTRONICS TECHNOLOGY INSTITUTE, Seongnam-si (KR)

(72) Inventors: Sang Hoon PARK, Seoul (KR); Kwang Ho AHN, Yongin-si (KR); Ki Jin KIM, Gwangju-si (KR)

(73) Assignee: KOREA ELECTRONICS TECHNOLOGY INSTITUTE, Seongnam-si (KR)

(21) Appl. No.: 14/256,356

(22) Filed: Apr. 18, 2014

(30) Foreign Application Priority Data
Apr. 19, 2013 (KR) 10-2013-0043303

(51) Int. Cl. H03K 5/1252

(52) U.S. Cl. CPC H03K 5/1252
USPC 327/56

(57) ABSTRACT

A low noise comparator for a high resolution ADC is provided. The comparator includes: an inputter configured to receive a signal and amplify the signal; and an outputter configured to output a result of comparing the signal output from the inputter, wherein an inductor is connected to an input terminal of an input element of at least one of the inputter and the outputter. Accordingly, the comparator can satisfy the gain value and the noise performance at the same time by using the inductor which has no voltage headroom problem.

### CROSS-REFERENCE TO RELATED APPLICATION(S) AND CLAIM OF PRIORITY

The present application claims the benefit under 35 U.S.C. §119(a) to a Korean patent application filed in the Korean Intellectual Property Office on Apr. 19, 2013, and assigned Serial No. 10-2013-0043303, the entire disclosure of which is hereby incorporated by reference.

### TECHNICAL FIELD OF THE INVENTION

The present invention relates generally to a comparator, and more particularly, to a comparator which is applicable to a high resolution Analogue-Digital Converter (ADC).

### BACKGROUND OF THE INVENTION

FIG. 1 illustrates a configuration of a related-art comparator. The comparator used in a related-art ADC uses a voltage of a sufficient range and thus guarantees a sufficient design margin by considering only a noise at a Sample-and-Hold (SH) block which is the first end of the ADC.

The related-art ADC which has a resolution of about 10 bits in a voltage condition of about 3.3V requires a performance of a resolution of about 3 mV. The noise level of the related-art comparator is a negligible signal size. However, the recent low power mobile environment has evolved into a low supply voltage environment of about 1V in order to minimize power consumption of batteries, and also, there is an increasing demand for an ADC which has a performance of a resolution of more than 12 bits to have a high data transmission rate.

To achieve this, the ADC should satisfy a performance of a resolution of about 200 μV and the comparator should satisfy a noise level of less than 10% considering a quantization noise and a thermal noise.

This noise level is about 20 μV and the low noise comparator is a very important issue, considering an inter-channel bandwidth which approaches GHz and is used in the recent wideband wireless communication system, and a very big flicker noise level which appears in the sub-micrometer level ultrafine Complementary Metal Oxide Semiconductor (CMOS) process.

However, as saving power consumption has become a very important issue in the recent electronic circuit system, the same high resolution processing is required in the low supply voltage environment. In addition, relatively great noise signals generated in the related-art comparator may cause an incorrect decision on minute input signals, thus reducing a Differential Non-Linearity (DNL) and an Integral Non-Linearity (INL), which are performance indicators of the ADC.

When the comparator is operated in the low supply voltage environment, the comparator is not able to meet the requirements of a gain value and a noise at the same time only by a single transistor due to a voltage headroom problem. Therefore, the comparator is designed to satisfy the gain value first and an additional hardware block to correct an error caused by the noise is required.

That is, the comparator required in the low voltage and high resolution ADC should satisfy not only the noise requirements but also the sufficient gain requirements. However, when those requirements cannot be satisfied at the same time, additional blocks to complement the performance are required, resulting in increased size and power consumption of the system.

### SUMMARY OF THE INVENTION

To address the above-discussed deficiencies of the prior art, it is a primary aspect of the present invention to provide a low noise comparator which can optimize a noise performance of the comparator which is essential to an ADC requiring a high resolution in a low power environment.

According to one aspect of the present invention, a comparator includes: an inputter configured to receive a signal and amplify the signal; and an outputter configured to output a result of comparing the signal output from the inputter, wherein the inputter includes an inductor connected to an input terminal of an input element which receives the signal.

The input terminal may be an input transistor, and the inductor may be connected to at least one of a gate and a source of the input transistor.

The inductor may be determined by an input impedance viewed from the gate of the input transistor.

The outputter may include an inductor connected to an input terminal of a coupling element which receives the signal output from the inputter.

The coupling element may be a coupling transistor, and the inductor may be connected to at least one of a gate and a source of the coupling transistor.

The inductor may be determined by an input impedance viewed from the gate of the coupling transistor.

According to another aspect of the present invention, a comparator includes: an inputter configured to receive a signal and amplify the signal; and an outputter configured to output a result of comparing the signal output from the inputter, wherein the outputter includes an inductor connected to an input terminal of a coupling element which receives the signal output from the inputter.

The coupling element may be a coupling transistor, and the inductor may be connected to at least one of a gate and a source of the coupling transistor.

The inductor may be determined by an input impedance viewed from the gate of the coupling transistor.

According to the exemplary embodiments of the present invention described above, the comparator can satisfy the gain value and the noise performance at the same time by using the inductor which has no voltage headroom problem.

Use of the comparator which can satisfy the gain and low noise at the same time may affect miniaturization and low power consumption of the entire system. By integrating the inductor having no DC power consumption into the transistor, the dual design variable of the inductor and transistor sizes can be used unlike in the related-art single variable design method depending on only the transistor size. Therefore, it is possible to design the comparator which can satisfy the required gain value and low noise performance at the same time.

In addition, as the system performance rapidly increases and all electronic devices are required to operate wirelessly for the convenience of users, an ADC which has a high resolution performance even in a low power operation is required. According to the exemplary embodiment of the present invention, an ADC which can satisfy a high resolution performance of more than 12 bits even in a low voltage environment of less than 1V can be implemented.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a configuration of a related-art comparator;

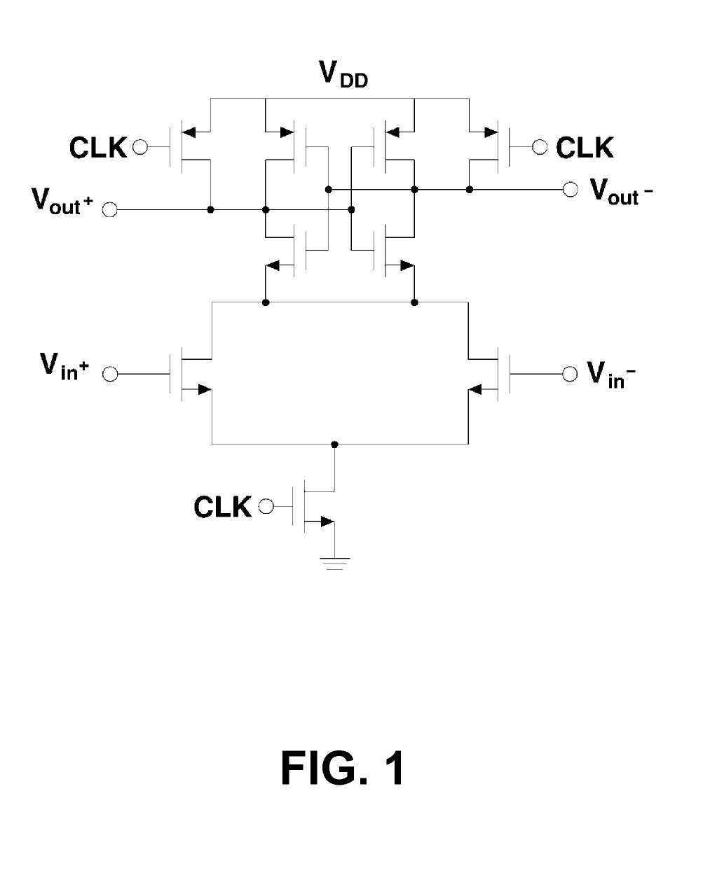

FIG. 2 is a circuit diagram of a comparator according to an exemplary embodiment of the present invention;

FIG. 3 is a view illustrating an equivalent circuit of a transistor provided in the comparator of FIG. 2;

Throughout the drawings, like reference numerals will be understood to refer to like parts, components and structures.

### DETAILED DESCRIPTION OF THE INVENTION

Reference will now be made in detail to the embodiment of the present general inventive concept, examples of which are illustrated in the accompanying drawings, wherein like reference numerals refer to the like elements throughout. The embodiment is described below in order to explain the present general inventive concept by referring to the drawings.

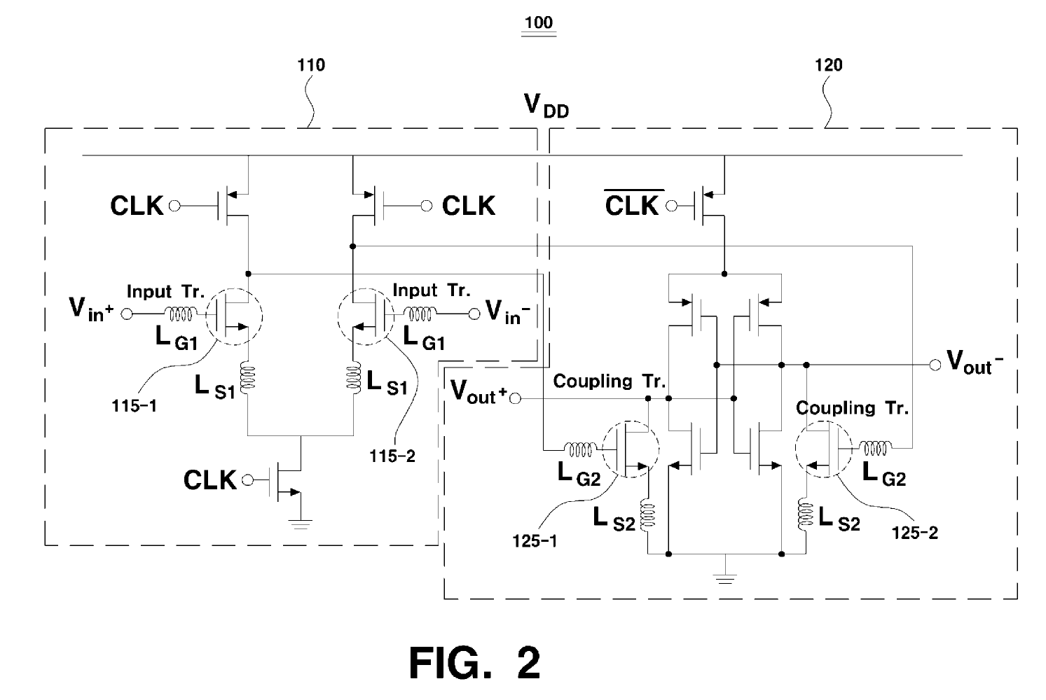

FIG. 2 is a circuit diagram of a comparator according to an exemplary embodiment of the present invention. The comparator 100 according to the exemplary embodiment of the present invention may be sealed and used in a high resolution ADC.

As shown in FIG. 2, the comparator 100 according to the exemplary embodiment of the present invention is a dual configuration divided into an inputter 110 and an outputter 120. Such a configuration of the comparator 100 is to solve a voltage headroom problem in a low supply voltage environment.

The inputter 110 receives a signal and amplifies the signal to a specific gain, and transmits the amplified signal to the outputter 120.

The outputter 120 amplifies the signal transmitted from the inputter 110 once more, compares the signal with a reference signal, and output a result of the comparing. Specifically, when the signal is larger than the reference signal, the outputter 120 latches a logic level “high”, and, when the signal is smaller than the reference signal, the outputter 120 latches a logic level “low”. Alternatively, the outputter 120 may output a result of the comparing in the reverse way.

The dual configuration divided into the inputter 110 and the outputter 120 is to operate optimally in the low supply voltage environment. In addition, the comparator 100 according to the exemplary embodiment of the present invention uses an inductor to reduce a noise. The inductor will be explained in detail below.

In order to reduce the noise, inductors L_{G1} and L_{S1} are connected to input terminals of input transistors 115-1 and 115-2 which are input elements to receive differential signals in the inputter 110. Specifically, the inductor L_{G1} is connected to gates of the input transistors 115-1 and 115-2 and the inductor L_{S1} is connected to sources of the input transistors 115-1 and 115-2.

Inductances of the inductors L_{G1} and L_{S1} are determined by an input impedance viewed from the gates of the input transistors 115-1 and 115-2.

In addition, in order to reduce the noise, inductors L_{G2} and L_{S2} are connected to input terminals of coupling transistors 125-1 and 125-2 which are coupling elements which are connected to the inputter 110 to receive signals in the outputter 120. Specifically, the inductor L_{G2} is connected to gates of the coupling transistors 125-1 and 125-2 and the inductor L_{S2} is connected to sources of the coupling transistors 125-1 and 125-2.

Inductances of the inductors L_{G2} and L_{S2} are determined by an input impedance viewed from the gates of the coupling transistors 125-1 and 125-2.

Since the input transistors 115-1 and 115-2 of the inputter 110 and the coupling transistors 125-1 and 125-2 of the outputter 120 are elements which can make the greatest contribution to considering an input equivalent noise of the comparator 100, the noise can be reduced by connecting the inductors L_{G1}, L_{S1}, L_{G2}, and L_{S2} to the input terminals of those transistors.

Since the inductors L_{G1}, L_{S1}, L_{G2}, and L_{S2} have no voltage drop in the DC (DC Voltage Drop=0V), the inductors may be free from the voltage headroom problem.

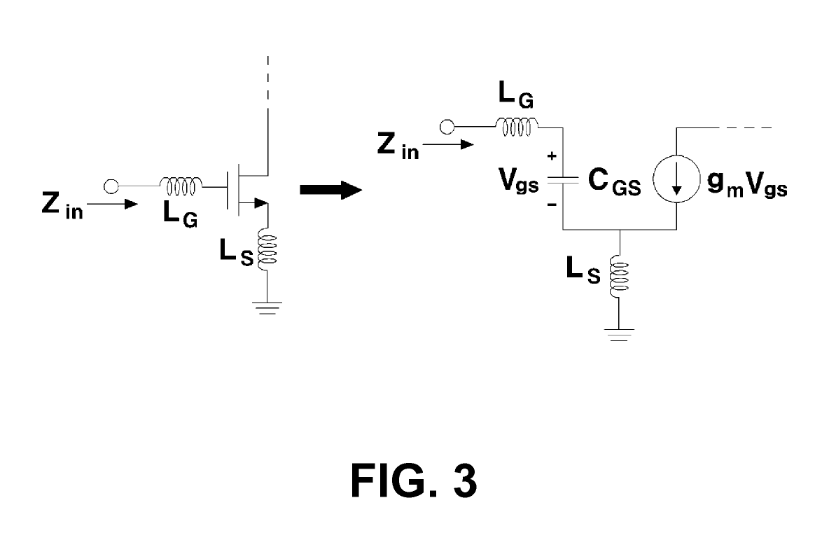

In order to explain a noise reduction effect which results from the inductors L_{G1}, L_{S1}, L_{G2}, and L_{S2} provided in the comparator 100 according to the exemplary embodiment, FIG. 3 illustrates an equivalent circuit of a transistor provided in the comparator 100.

The equivalent circuit of FIG. 3 may be equally applied to the input transistors 115-1 and 115-2 of the inputter 110 and the coupling transistors 125-1 and 125-2 of the outputter 120 shown in FIG. 2 and interpreted.

An input impedance may be calculated by using Equation 1 through the equivalent circuit of FIG. 3:

$${V}_{x} = {I}_{x} ( \frac{1}{jω {C}_{GS}} ) + jω {L}_{S} ( {I}_{x} + {g}_{m} {I}_{x} \frac{1}{jω {C}_{GS}} ) \\ Z ( ω ) = \frac{{V}_{x}}{{I}_{x}} = jω {L}_{G} + ( \frac{1}{jω {C}_{GS}} ) + jω {L}_{S} ( 1 + {g}_{m} ( \frac{1}{jω {C}_{GS}} ) ) \qquad Equation 1$$

Equation 1 indicates that the input impedance can be adjusted by using an inductor and also a gain necessary for the transistor can be satisfied separately from the input impedance. Accordingly, since the input impedance can be adjusted to minimize the input equivalent noise, the input equivalent noise of the comparator 100 can be minimized.

The important thing herein is not minimizing a noise that the transistor has by using the inductor. Since the transistor should be adjusted to obtain a necessary gain, it is impossible to arbitrarily adjust the noise of the transistor. However, since the comparator 100 can make a normal decision as long as the input equivalent noise of the comparator 100 rather than the noise of the transistor is small so as not to affect a minimum level of a transmitted signal, the equivalent circuit has a very effective configuration to improve a noise performance of the comparator 100.

According to Equation 1, it is possible to adjust both the real number and the imaginary number of the input impedance by adjusting the inductance. Therefore, a certain input impedance can be embodied.

Up to now, the exemplary embodiment of the comparator which is sealed in the high resolution ADC and can reduce the noise has been described.

In the above-described exemplary embodiment, the inductors are used in both the inputter 110 and the outputter 120 of the comparator 100 in order to reduce the noise. However, this is merely an example. Using the inductors in one of the inputter 110 and the outputter 120 can belong to the scope of the present invention.

In addition, the comparator 100 according to the exemplary embodiment is designed to be sealed in the ADC. However, the comparator 100 may be used in other elements.

In addition, the inductors may be connected to one of the gate and the source of the transistor rather than being connected both of the gate and the source of the transistor. In addition, reducing the noise by connecting the inductors to another type of input element in addition to the transistor can belong to the scope of the present invention.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A comparator comprising:
an inputter configured to receive a signal and amplify the signal; and
an outputter configured to output a result of comparing the signal output from the inputter,
wherein the inputter comprises an inductor connected to an input terminal of an input element which receives the signal.

2. The comparator of claim 1, wherein the input terminal is an input transistor, and
wherein the inductor is connected to at least one of a gate and a source of the input transistor.

3. The comparator of claim 2, wherein the inductor is determined by an input impedance viewed from the gate of the input transistor.

4. The comparator of claim 1, wherein the outputter comprises an inductor connected to an input terminal of a coupling element which receives the signal output from the inputter.

5. The comparator of claim 4, wherein the coupling element is a coupling transistor, and
wherein the inductor is connected to at least one of a gate and a source of the coupling transistor.

6. The comparator of claim 5, wherein the inductor is determined by an input impedance viewed from the gate of the coupling transistor.

7. A comparator comprising:
an inputter configured to receive a signal and amplify the signal; and
an outputter configured to output a result of comparing the signal output from the inputter,
wherein the outputter comprises an inductor connected to an input terminal of a coupling element which receives the signal output from the inputter.

8. The comparator of claim 7, wherein the coupling element is a coupling transistor, and
wherein the inductor is connected to at least one of a gate and a source of the coupling transistor.

9. The comparator of claim 8, wherein the inductor is determined by an input impedance viewed from the gate of the coupling transistor.
